(19) United States
(12) Patent Application Publication
(10) Pub. No.: US 2021/0088287 A1
(43) Pub. Date: Mar. 25, 2021

(54) WATER-COOLING PUMP STRUCTURE WITH CHECK VALVES AND WATER-COOLING MODULE THEREOF

(71) Applicant: ASIA VITAL COMPONENTS CO., LTD., New Taipei City (TW)

(72) Inventor: Wen-Ji Lan, New Taipei City (TW)

(21) Appl. No.: 16/576,788

(22) Filed: Sep. 20, 2019

(51) Int. Cl. F28D 15/00; F28F 23/02

(52) U.S. Cl. CPC F28D 15/00; F28F 2250/08; F28F 23/02

(57) ABSTRACT

A water-cooling pump structure with check valves and a water-cooling module thereof including a first pump unit, a first check valve, a second pump unit, a second check valve, a first connector assembly, a second connector assembly, a pipe body assembly and a heat dissipation unit. The first and second check valves are respectively mounted at the first and second water outlets of the first and second pump units. By means of the arrangement of a first sealing member inside the first check valve, the cooling liquid is prevented from flowing back to the first pump chamber. Therefore, the problem of the backflow of the cooling liquid can be totally solved. Moreover, the heat dissipation efficiency can be greatly enhanced.

### BACKGROUND OF THE INVENTION

### 1. Field of the Invention

The present invention relates generally to a water-cooling pump structure with check valves and a water-cooling module thereof, and more particularly to a water-cooling pump structure with check valves and a water-cooling module thereof, which can prevent the cooling liquid from flowing back.

### 2. Description of the Related Art

It is known that a great amount of various chips such as central processing unit, graphics chip and Northbridge/Southbridge chipset are used in the current computer or electronic industries. The arrangement density of these chips has become higher and higher and the operation frequency has become faster and faster. As a result, in operation, the heat generated by these chips as heat generation components has become higher and higher. In operation, in the case that the temperature is too high, the heat generation components will malfunction or even burn down. Therefore, in order to effectively reduce the heat, various heat dissipation devices are provided on the market. The heat dissipation devices are tightly attached to the heating surfaces of the heat generation components so as to dissipate the heat by way of conduction, convection or radiation and keep the heat generation components operating at normal working temperature.

The most often seen heat dissipation device is made of thermo-conductive metal (such as aluminum or copper) by means of various processing procedures. The heat dissipation device is composed of a base seat, multiple radiating fins and a cooling fan. The base seat is in tight contact with the heat generation component to directly conduct the heat to the radiating fins. Heat convection takes place between the surface of the radiating fins and the ambient air so as to dissipate the heat to outer side. Alternatively, a heat pipe can be combined with the heat dissipation device to enhance the heat dissipation effect. The heat pipe has a closed tubular body, in which a liquid cooling medium is filled. The main composition of the cooling medium is water. The rest of the cooling medium is composed of special compositions capable of enhancing the heat transfer ability of the liquid. One end of the heat pipe is an evaporation end in contact with the heat generation component to absorb the heat thereof. After the cooling medium absorbs the heat, the cooling medium is evaporated into vapor phase and moves to the other end of the heat pipe, that is, the condensation end to dissipate the heat. Accordingly, the heat pipe provides a closed heat dissipation circulation travel. The cooling medium serves to carry away a great amount of heat at one time to enhance the heat dissipation efficiency.

In addition, there is a water-cooling thermal module simply employing liquid circulation to dissipate the heat. The water-cooling thermal module employs a circulating pump to drive a cooling liquid with large specific heat to absorb heat, (which is generally water). When the cooling liquid flows through the heat generation component, the cooling liquid can absorb the heat. Then the cooling liquid flows away to carry away the heat from the heat generation component. When the cooling liquid flows through a pipeline or a water reservoir, the cooling liquid releases the heat to achieve the object of heat dissipation. In order to enhance the heat dissipation efficiency, some manufacturers develop a water-cooling thermal module in which multiple pumps are up and down stacked to dissipate the heat. The cooling liquid in the respective pumps is collected and then flows out through the pipe bodies. Accordingly, the cooling liquid is continuously circulated to dissipate the heat. However, according to such arrangement, in case one of the pumps is damaged and fails to drive the internal cooling liquid to flow, this will lead to the problem of backflow of the cooling liquid. Therefore, the cooling liquid can hardly smoothly circulate to dissipate the heat. As a result, the heat dissipation efficiency will be deteriorated.

### SUMMARY OF THE INVENTION

It is therefore a primary object of the present invention to provide a water-cooling pump structure with check valves, which can prevent the cooling liquid from flowing back.

It is a further object of the present invention to provide the above water-cooling pump structure with check valves, which can greatly enhance the heat dissipation efficiency.

It is still a further object of the present invention to provide a water-cooling module, which can prevent the cooling liquid from flowing back.

It is still a further object of the present invention to provide the above water-cooling module, which can greatly enhance the heat dissipation efficiency.

To achieve the above and other objects, the water-cooling pump structure with check valves of the present invention includes a first pump unit, a first check valve, a second pump unit, a second check valve, a first connector assembly and a second connector assembly. The first pump unit has a first pump case forming a first pump chamber. A first water inlet and a first water outlet are formed on the first pump case. The first pump chamber communicates with the first water inlet and the first water outlet. The first check valve is correspondingly connected with the first water outlet. The second pump unit has a second pump case forming a second pump chamber. A second water inlet and a second water outlet are formed on the second pump case. The second pump chamber communicates with the second water inlet and the second water outlet. The second check valve is correspondingly connected with the second water outlet. The first connector assembly has a first water incoming section, a second water incoming section and a first water outgoing section. The first water incoming section is correspondingly connected with the first check valve. The second water incoming section is correspondingly connected with the second check valve. The second connector assembly has a third water incoming section, a second water outgoing section and a third water outgoing section. The second water outgoing section is correspondingly connected with the first water inlet. The third water outgoing section is correspondingly connected with the second water inlet.

To achieve the above and other objects, the water-cooling module of the present invention includes a first pump unit, a first check valve, a second pump unit, a second check valve, a first connector assembly, a second connector assembly, a pipe body assembly and a heat dissipation unit. The first pump unit has a first pump case forming a first pump chamber. A first water inlet and a first water outlet are formed on the first pump case. The first pump chamber communicates with the first water inlet and the first water outlet. The first check valve is correspondingly connected with the first water outlet. The second pump unit has a second pump case forming a second pump chamber. A second water inlet and a second water outlet are formed on the second pump case. The second pump chamber communicates with the second water inlet and the second water outlet. The second check valve is correspondingly connected with the second water outlet. The first connector assembly has a first water incoming section, a second water incoming section and a first water outgoing section. The first water incoming section is correspondingly connected with the first check valve. The second water incoming section is correspondingly connected with the second check valve. The second connector assembly has a third water incoming section, a second water outgoing section and a third water outgoing section. The second water outgoing section is correspondingly connected with the first water inlet. The third water outgoing section is correspondingly connected with the second water inlet. The pipe body assembly includes a first pipe body and a second pipe body. One end of the first pipe body correspondingly communicates with the first water outgoing section. One end of the second pipe body correspondingly communicates with the third water incoming section. The heat dissipation unit has an inlet and an outlet. The inlet correspondingly communicates with the other end of the first pipe body. The outlet correspondingly communicates with the other end of the second pipe body. The heat dissipation unit is formed with an internal communication chamber for a cooling liquid to flow through. The communication chamber communicates with the inlet and the outlet.

According to the structural design of the present invention, when the water-cooling module starts to operate, the cooling liquid in the heat dissipation unit will flow through the outlet into the second pipe body and then flow into the third water incoming section. After flowing through the third water incoming section of the second connector assembly, the flow of the cooling liquid is divided. Part of the liquid will flow from the second water outgoing section to the second communication pipe and then flow into the first pump chamber of the first pump unit from the first water inlet. Then, the cooling liquid in the first pump chamber will pass through the first water outlet to flow into the first space of the first check valve. Due to the pressure of the cooling liquid, the first sealing member disposed in the first space will be pushed and opened forward. Accordingly, the cooling liquid can smoothly flow into the second space and then flow into the first communication pipe and then flow into the first water incoming section of the first connector assembly.

The other part of the divided cooling liquid will flow from the third water outgoing section to the fourth communication pipe and then flow into the second pump chamber of the second pump unit from the second water inlet. Then, the cooling liquid in the second pump chamber will pass through the second water outlet to flow into the third space of the second check valve. Due to the pressure of the cooling liquid, the second sealing member disposed in the third space will be pushed and opened forward.

Accordingly, the cooling liquid can smoothly flow into the fourth space and then flow into the third communication pipe and then flow into the second water incoming section of the first connector assembly. The cooling liquid flowing into the second water incoming section and the cooling liquid flowing into the first water incoming section are collected and then together exhausted to the first water outgoing section. Then, the cooling liquid passes through the first pipe body to flow back to the communication chamber of the heat dissipation unit. Accordingly, the cooling liquid is continuously circulated to complete the liquid-cooling circulation of the water-cooling module.

The first and second check valves are respectively mounted at the first and second water outlets. Accordingly, in case any of the pump units is damaged and fails to drive the cooling liquid to flow, the first sealing member (or the second sealing member) inside the first check valve (or the second check valve) can prevent the cooling liquid from flowing back to the first pump chamber (or the second pump chamber). Therefore, the backflow of the cooling liquid can be avoided and the heat dissipation efficiency can be greatly enhanced.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein:

FIG. 1A is a perspective exploded view of a first embodiment of the water-cooling pump structure with check valves of the present invention;

FIG. 1B is a perspective assembled view of the first embodiment of the water-cooling pump structure with check valves of the present invention;

FIG. 2A is a perspective exploded view of the first check valve of the present invention;

FIG. 2B is a perspective assembled view of the first check valve of the present invention;

FIG. 2C is a sectional view of the first check valve of the present invention;

FIG. 2D is a sectional view of the second check valve of the present invention;

FIG. 3A is a perspective exploded view of a first embodiment of the water-cooling module of the present invention;

FIG. 3B is a perspective assembled view of the first embodiment of the water-cooling module of the present invention, showing the operation thereof;

FIG. 3C is a sectional view of the first embodiment of the water-cooling module of the present invention;

FIG. 3D is another sectional view of the first embodiment of the water-cooling module of the present invention;

FIG. 4 is a perspective assembled view of a second embodiment of the water-cooling module of the present invention; and

FIG. 5 is a perspective assembled view of a third embodiment of the water-cooling module of the present invention.

### DETAILED DESCRIPTION OF THE PREFERRED EMBODIMENTS

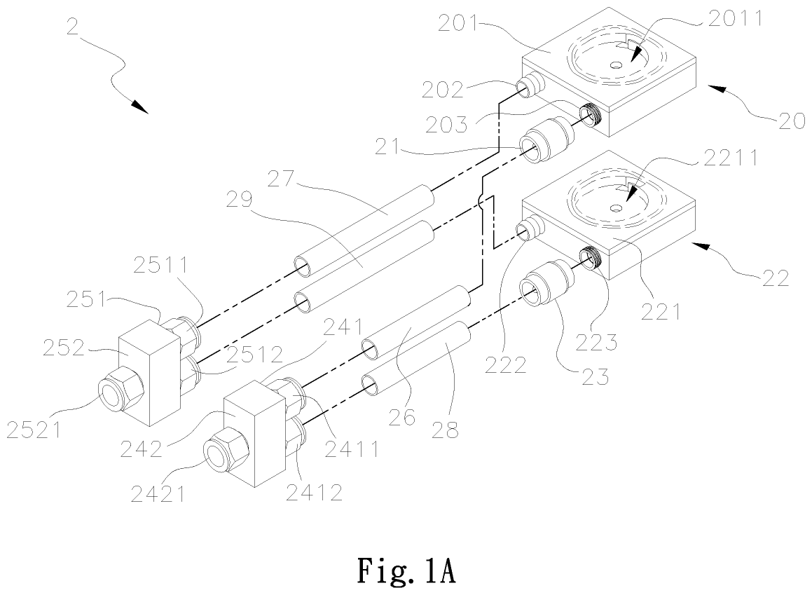

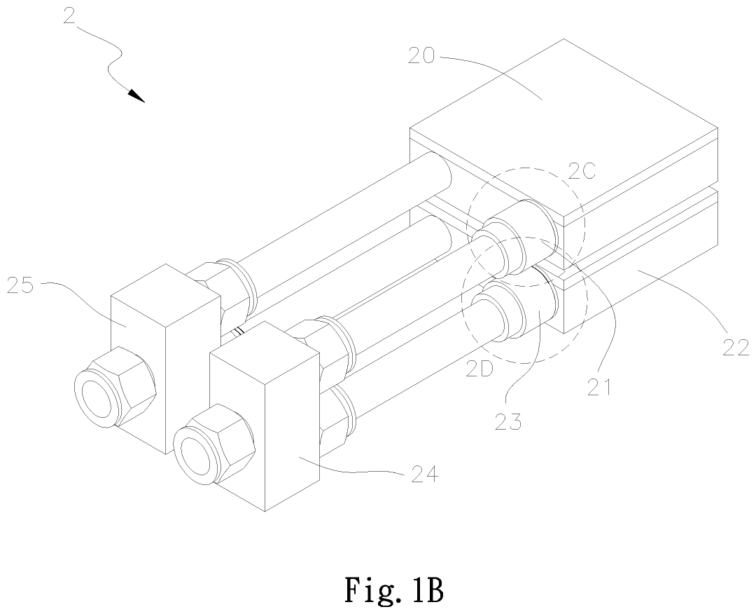

Please refer to FIGS. 1A and 1B. FIG. 1A is a perspective exploded view of a first embodiment of the water-cooling pump structure with check valves of the present invention. FIG. 1B is a perspective assembled view of the first embodiment of the water-cooling pump structure with check valves of the present invention. According to the first embodiment, the water-cooling pump structure 2 with check valves of the present invention includes a first pump unit 20, a first check valve 21, a second pump unit 22, a second check valve 23, a first connector assembly 24 and a second connector assembly 25. The first pump unit 20 has a first pump case 201 forming a first pump chamber 2011. A first water inlet 202 and a first water outlet 203 are formed on the first pump case 201. The first pump chamber 2011 communicates with the first water inlet 202 and the first water outlet 203. The first water outlet 203 is correspondingly connected with the first check valve 21.

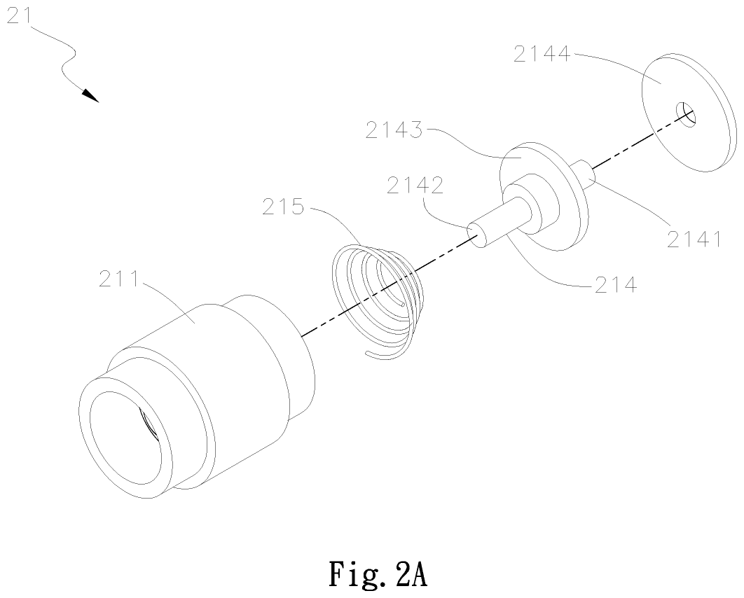

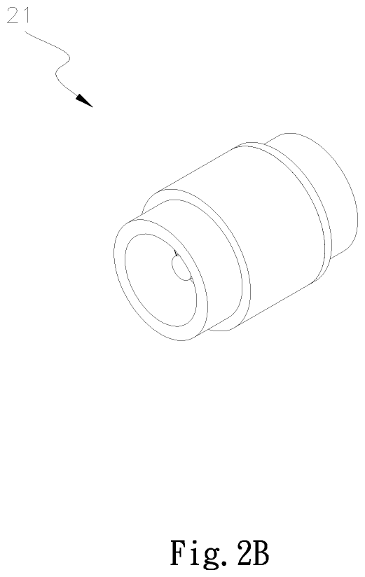

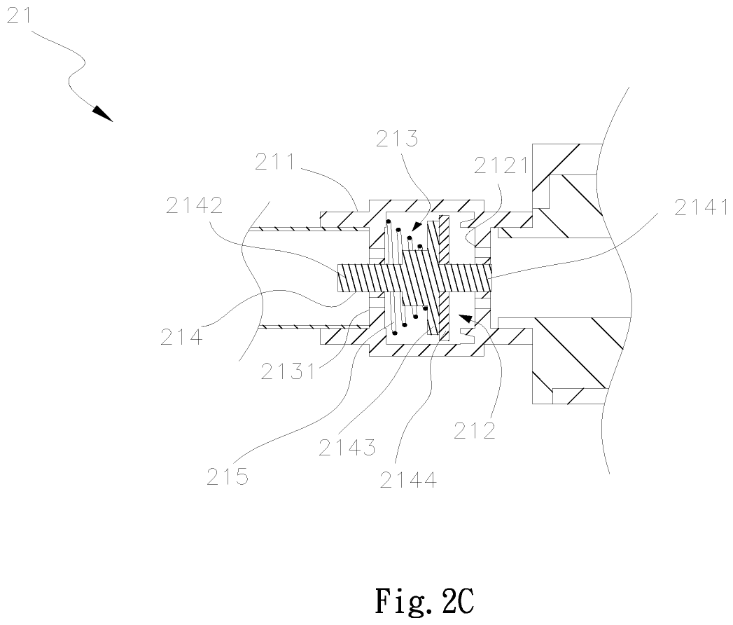

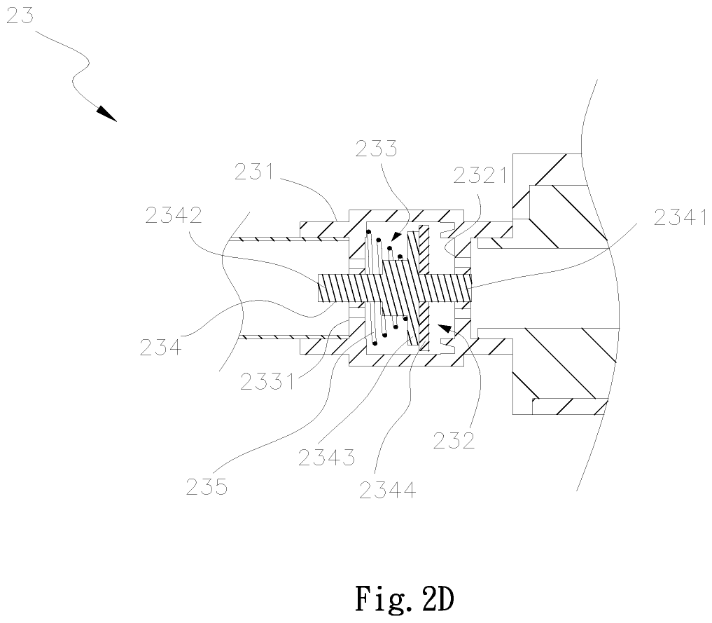

Please now refer to FIGS. 2A, 2B and 2C, which show the internal structure of the first check valve 21. The first check valve 21 has a first valve body 211 formed with a first space 212 and a second space 213 inside. The first space 212 has a first seat section 2121 and the second space 213 has a second seat section 2131. A first rod body 214 has a first base section 2143 and a first sealing member 2144. Two ends of the first rod body 214 extend to form a first extension end 2141 and a second extension end 2142. The first and second extension ends 2141, 2142 are axially movably inserted in the first and second seat sections 2121, 2131 respectively. The first sealing member 2144 is disposed on one side of the first base section 2143 proximal to the first space 212. Two ends of a first elastic member 215 respectively abut against the first base section 2143 of the first rod body 214 and the inner wall face of the first valve body 211. The first water outlet 203 of the first pump unit 20 correspondingly communicates with the first space 212.

The second pump unit 22 has a second pump case 221 forming a second pump chamber 2211. A second water inlet 222 and a second water outlet 223 are formed on the second pump case 221. The second pump chamber 2211 communicates with the second water inlet 222 and the second water outlet 223. The second water outlet 223 is correspondingly connected with the second check valve 23.

Please further refer to FIG. 2D, which is a sectional view directly showing the second check valve 23. The second check valve 23 has an appearance identical to that of the first check valve 21 (with reference to FIGS. 2A and 2B) and thus will not be shown with any drawing. The second check valve 23 has a second valve body 231 formed with a third space 232 and a fourth space 233 inside. The third space 232 has a third seat section 2321 and the fourth space 233 has a fourth seat section 2331. A second rod body 234 has a second base section 2343 and a second sealing member 2344. Two ends of the second rod body 234 extend to form a third extension end 2341 and a fourth extension end 2342. The third and fourth extension ends 2341, 2342 are axially movably inserted in the third and fourth seat sections 2321, 2331 respectively. The second sealing member 2344 is disposed on one side of the second base section 2343 proximal to the third space 232. Two ends of a second elastic member 235 respectively abut against the second base section 2343 of the second rod body 234 and the inner wall face of the second valve body 231. The second water outlet 223 of the second pump unit 22 correspondingly communicates with the third space 232.

The first pump unit 20 has a first communication pipe 26 and a second communication pipe 27. One end of the first communication pipe 26 is correspondingly connected with the second space 213 of the first check valve 21. One end of the second communication pipe 27 is correspondingly connected with the first water inlet 202 of the first pump unit 20.

The second pump unit 22 has a third communication pipe 28 and a fourth communication pipe 29. One end of the third communication pipe 28 is correspondingly connected with the fourth space 233 of the second check valve 23. One end of the fourth communication pipe 29 is correspondingly connected with the second water inlet 222 of the second pump unit 22.

The first connector assembly 24 has a first side 241 and a second side 242. The first side 241 is formed with a first water incoming section 2411 and a second water incoming section 2412. The second side 242 is formed with a first water outgoing section 2421. The first water outgoing section 2421 communicates with the first and second water incoming sections 2411, 2412. The first water incoming section 2411 is connected with the other end of the first communication pipe 26 opposite to the end connected with the first check valve 21. The second water incoming section 2412 is connected with the other end of the third communication pipe 28 opposite to the end connected with the second check valve 23.

The second connector assembly 25 has a third side 251 and a fourth side 252. The third side 251 is formed with a second water outgoing section 2511 and a third water outgoing section 2512. The fourth side 252 is formed with a third water incoming section 2521. The third water incoming section 2521 communicates with the second and third water outgoing sections 2511, 2512. The second water outgoing section 2511 is connected with the other end of the second communication pipe 27 opposite to the end connected with the first water inlet 202. The third water incoming section 2521 is connected with the other end of the fourth communication pipe 29 opposite to the end connected with the second water inlet 222.

In this embodiment, the first and second connector assemblies 24, 25 are, but not limited to, three-way connectors for illustration purposes. Alternatively, the first and second connector assemblies 24, 25 can be four-way or multi-way connectors in accordance with the number of the water-cooling pump structures of the user. In other words, in the present invention, the first and second pump units 20, 22, (that is, two pump units) are exemplified for illustration purposes. By means of the structures and principles of the three-way connectors, when the internal cooling liquid 5 passes through the first and second connector assemblies 24, 25, the flow of the cooling liquid 5 can be divided or collected.

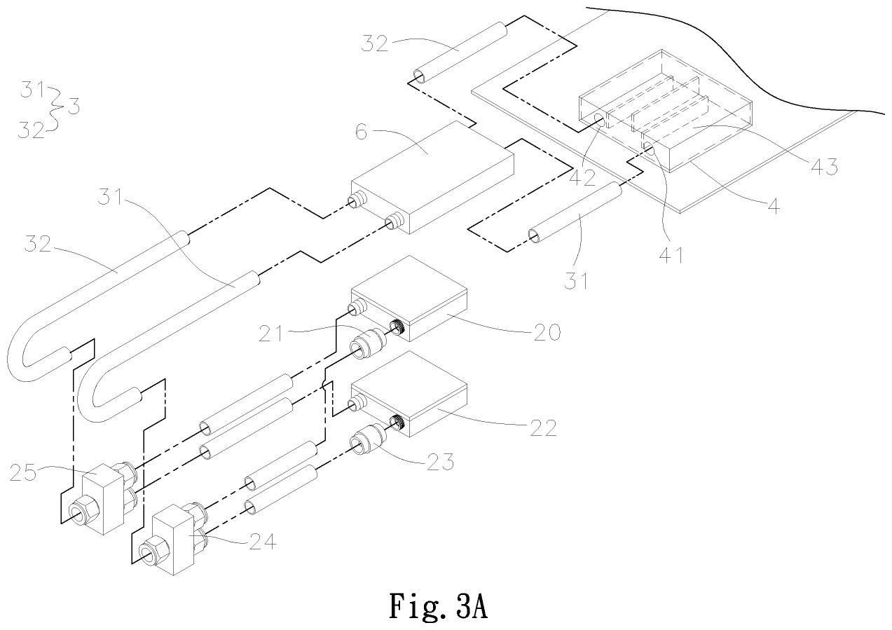

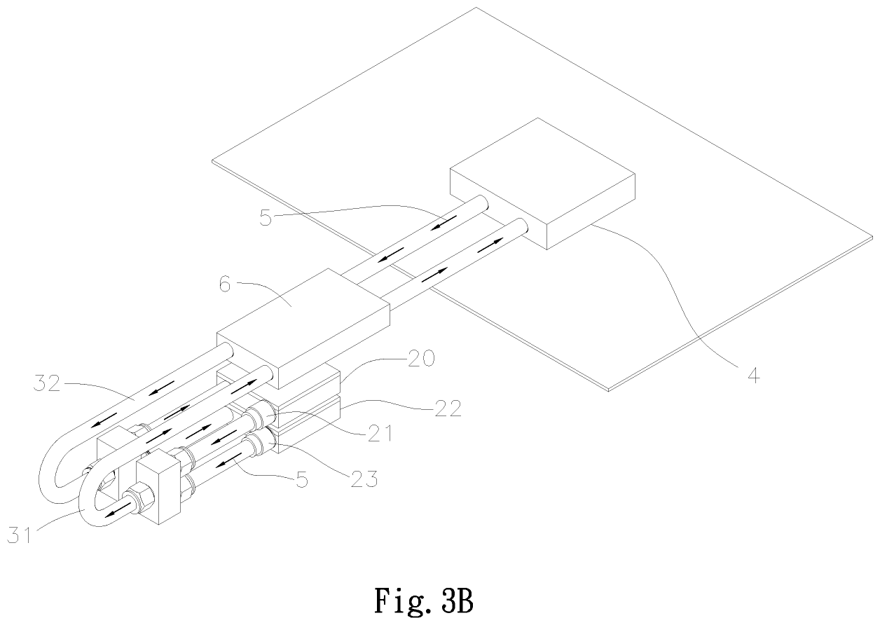

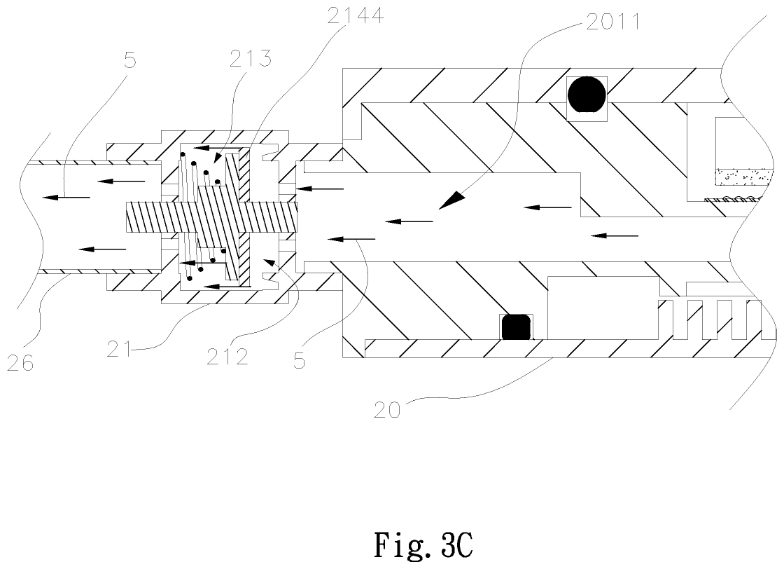

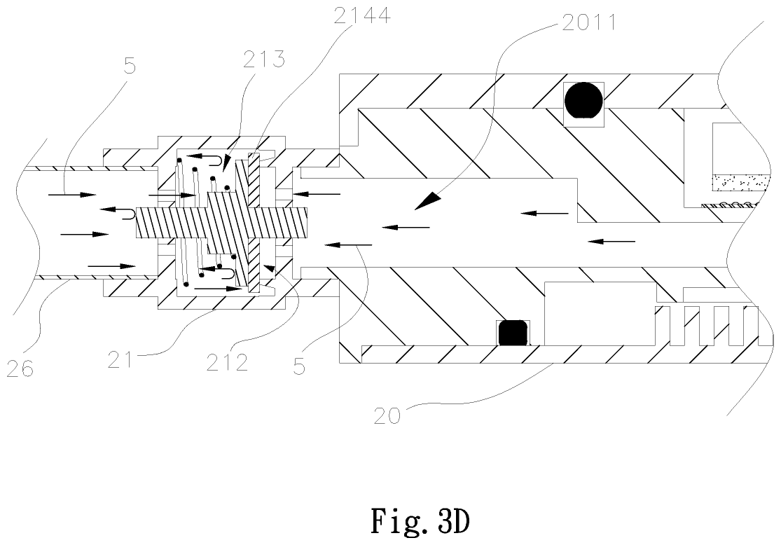

Please now refer to FIGS. 3A, 3B, 3C and 3D. FIG. 3A is a perspective exploded view of a first embodiment of the water-cooling module of the present invention. FIG. 3B is a perspective assembled view of the first embodiment of the water-cooling module of the present invention, showing the operation thereof. FIG. 3C is a sectional view of the first embodiment of the water-cooling module of the present invention. FIG. 3D is another sectional view of the first embodiment of the water-cooling module of the present invention. In the first embodiment, the water-cooling module is partially identical to the above water-cooling pump structure 2 with check valves of the present invention in component and component relationship and thus will not be redundantly described hereinafter. In addition to the above water-cooling pump structure 2 with check valves, the water-cooling module further includes a pipe body assembly 3 and a heat dissipation unit 4. The pipe body assembly 3 includes a first pipe body 31 and a second pipe body 32. One end of the first pipe body 31 correspondingly communicates with the first water outgoing section 2421 of the first connector assembly 24. One end of the second pipe body 32 correspondingly communicates with the third water incoming section 2521 of the second connector assembly 25.

The heat dissipation unit 4 has an inlet 41 and an outlet 42. The inlet 41 communicates with the other end of the first pipe body 31 opposite to the end connected with the first water outgoing section 2421 of the first connector assembly 24. The outlet 42 communicates with the other end of the second pipe body 32 opposite to the end connected with the third water incoming section 2521 of the second connector assembly 25.

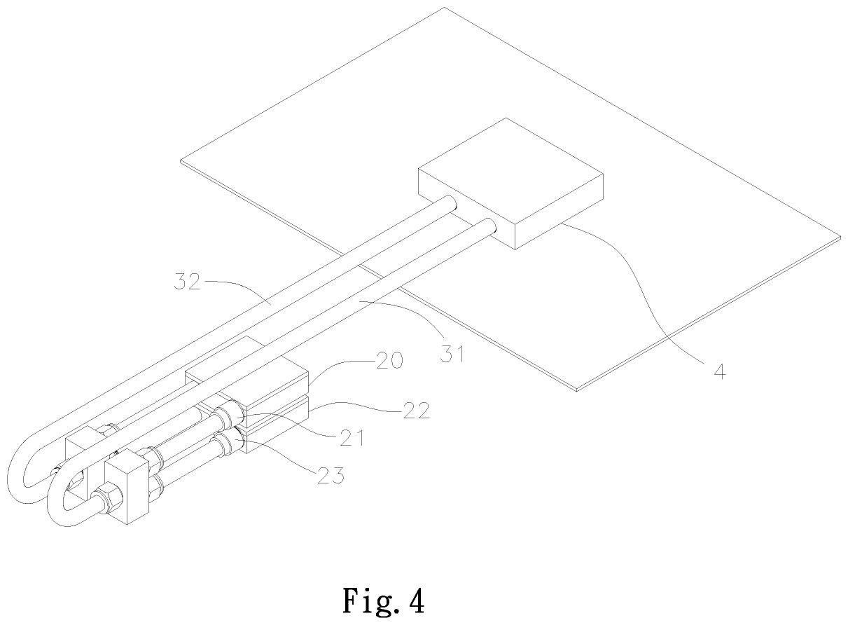

In addition, in this embodiment, the thermal module further has a water reservoir 6. One side of the water reservoir 6 is correspondingly connected with the pipe body assembly 3. The other side of the water reservoir 6 correspondingly communicates with the inlet 41 and the outlet 42 of the heat dissipation unit 4. It should be noted that the water reservoir 6 can be omitted (as shown in FIG. 4) to achieve the same effect of the present invention.

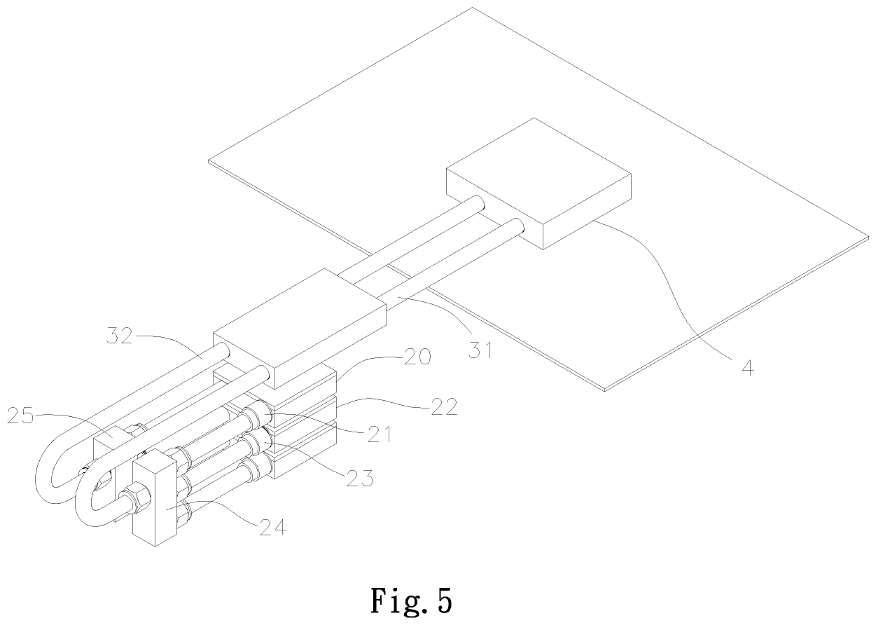

Moreover, in this embodiment, the water-cooling module of the present invention has, but not limited to, the first and second pump units 20, 22, (that is, two pump units) for illustration purposes. In practice, three (or more) pump units can be stacked (as shown in FIG. 5) in accordance with the designed arrangement of the user. Certainly, it can be further understood that according to the number of the arranged pump units, the three-way connectors can be replaced with four-way connectors (or multi-way connectors). In this case, the numbers of the corresponding communication pipes and check valves should be also increased to form a complete water-cooling module.

According to the structural design of the water-cooling module, when one side of the heat dissipation unit 4 of the water-cooling module contacts a heat generation component (not shown) to operate, the cooling liquid 5 in the heat dissipation unit 4 will first flow through the outlet 42 into the water reservoir 6 and then flow into the second pipe body 32 and then flow into the third water incoming section 2521. After flowing through the third water incoming section 2521 of the second connector assembly 25, the flow of the cooling liquid 5 is divided. Part of the liquid will flow from the second water outgoing section 2511 to the second communication pipe 27 and then flow into the first pump chamber 2011 of the first pump unit 20 from the first water inlet 202. Then, the cooling liquid 5 in the first pump chamber 2011 will pass through the first water outlet 203 to flow into the first space 212 of the first check valve 21. Due to the pressure of the cooling liquid 5, the first sealing member 2144 disposed in the first space 212 will be pushed and opened toward the second space 213. Accordingly, the cooling liquid 5 can smoothly flow into the second space 213 and then flow into the first communication pipe 26 and then flow into the first water incoming section 2411 of the first connector assembly 24.

The other part of the divided cooling liquid 5 will flow from the third water outgoing section 2512 to the fourth communication pipe 29 and then flow into the second pump chamber 2211 of the second pump unit 22 from the second water inlet 222. Then, the cooling liquid 5 in the second pump chamber 2211 will pass through the second water outlet 223 to flow into the third space 232 of the second check valve 23. Due to the pressure of the cooling liquid 5, the second sealing member 2344 disposed in the third space 232 will be pushed and opened toward the fourth space 233. Accordingly, the cooling liquid 5 can smoothly flow into the fourth space 233 and then flow into the third communication pipe 28 and then flow into the second water incoming section 2412 of the first connector assembly 24. The cooling liquid 5 flowing into the second water incoming section 2412 and the cooling liquid 5 flowing into the first water incoming section 2411 are collected in the first connector assembly 24 and then together exhausted to the first water outgoing section 2421. Then, the cooling liquid 5 sequentially passes through the first pipe body 31 and the water reservoir 6 to flow back to a communication chamber 43 of the heat dissipation unit 4, which is composed of multiple flow ways). Accordingly, the cooling liquid 5 is continuously circulated to complete the liquid-cooling circulation of the water-cooling module.

The first and second check valves 21, 23 are respectively mounted at the first and second water outlets 203, 223 of the first and second pump units 20, 22. Accordingly, in case any of the pump units, that is, any of the first and second pump units 20, 22 is damaged and fails to drive the cooling liquid 5 to flow, (in FIGS. 3C and 3D, the first pump unit 20 is exemplified for illustration purposes), the cooling liquid 5 will flow back. When the cooling liquid 5 flows back, it will be impossible to smoothly carry out the circulation of the cooling liquid 5 within the water-cooling module. However, by means of the arrangement of the first sealing member 2144 (or the second sealing member 2344) inside the first check valve 21 (or the second check valve 23), the cooling liquid 5 is prevented from flowing back to the first pump chamber 2011 (or the second pump chamber 2211). Therefore, the problem of the backflow of the cooling liquid 5 can be totally solved (as clearly shown in FIG. 3D). Moreover, the heat dissipation efficiency can be greatly enhanced.

In addition, in order to achieve better heat dissipation effect, at least one heat dissipation component (such as radiating fins and cooling radiator) can be added to the thermal module so as to heat-exchange with the cooling liquid 5.

In conclusion, in comparison with the conventional water-cooling module, the present invention has the following advantages:

1. The cooling liquid is prevented from flowing back.

2. The heat dissipation efficiency is greatly enhanced.

The present invention has been described with the above embodiments thereof and it is understood that many changes and modifications in such as the form or layout pattern or practicing step of the above embodiments can be carried out without departing from the scope and the spirit of the invention that is intended to be limited only by the appended claims.

What is claimed is:

1. A water-cooling pump structure with check valves, comprising:
a first pump unit having a first pump case forming a first pump chamber, a first water inlet and a first water outlet being formed on the first pump case, the first pump chamber communicating with the first water inlet and the first water outlet;
a first check valve correspondingly connected with the first water outlet;
a second pump unit having a second pump case forming a second pump chamber, a second water inlet and a second water outlet being formed on the second pump case, the second pump chamber communicating with the second water inlet and the second water outlet;
a second check valve correspondingly connected with the second water outlet;
a first connector assembly having a first water incoming section, a second water incoming section and a first water outgoing section, the first water incoming section being correspondingly connected with the first check valve, the second water incoming section being correspondingly connected with the second check valve; and
a second connector assembly having a third water incoming section, a second water outgoing section and a third water outgoing section, the second water outgoing section being correspondingly connected with the first water inlet, the third water outgoing section being correspondingly connected with the second water inlet.

2. The water-cooling pump structure with check valves as claimed in claim 1, wherein the first pump unit has a first communication pipe and a second communication pipe, two ends of the first communication pipe being respectively connected with the first check valve and the first water incoming section, two ends of the second communication pipe being respectively connected with the first water inlet and the second water outgoing section.

3. The water-cooling pump structure with check valves as claimed in claim 1, wherein the second pump unit has a third communication pipe and a fourth communication pipe, two ends of the third communication pipe being respectively connected with the second check valve and the second water incoming section, two ends of the fourth communication pipe being respectively connected with the second water inlet and the third water outgoing section.

4. The water-cooling pump structure with check valves as claimed in claim 1, wherein the first connector assembly has a first side and a second side, the first side being formed with the first water incoming section and the second water incoming section, the second side being formed with the first water outgoing section, the first and second water incoming sections communicating with the first water outgoing section.

5. The water-cooling pump structure with check valves as claimed in claim 1, wherein the second connector assembly has a third side and a fourth side, the third side being formed with the second water outgoing section and the third water outgoing section, the fourth side being formed with the third water incoming section, the second and third water outgoing sections communicating with the third water incoming section.

6. The water-cooling pump structure with check valves as claimed in claim 1, wherein the first check valve has a first valve body formed with a first space and a second space inside, the first space having a first seat section, the second space having a second seat section, a first rod body having a first base section and a first sealing member, two ends of the first rod body extending to form a first extension end and a second extension end, the first and second extension ends being axially movably inserted in the first and second seat sections respectively, the first sealing member being disposed on one side of the first base section proximal to the first space, two ends of a first elastic member respectively abutting against the first base section of the first rod body and an inner wall face of the first valve body.

7. The water-cooling pump structure with check valves as claimed in claim 6, wherein the first water outlet of the first pump unit correspondingly communicates with the first space and the first water incoming section correspondingly communicates with the second space.

8. The water-cooling pump structure with check valves as claimed in claim 1, wherein the second check valve has a second valve body formed with a third space and a fourth space inside, the third space having a third seat section, the fourth space having a fourth seat section, a second rod body having a second base section and a second sealing member, two ends of the second rod body extending to form a third extension end and a fourth extension end, the third and fourth extension ends being axially movably inserted in the third and fourth seat sections respectively, the second sealing member being disposed on one side of the second base section proximal to the third space, two ends of a second elastic member respectively abutting against the second base section of the second rod body and an inner wall face of the second valve body.

9. The water-cooling pump structure with check valves as claimed in claim 8, wherein the second water outlet of the second pump unit correspondingly communicates with the third space and the second water incoming section correspondingly communicates with the fourth space.

10. A water-cooling module comprising:
a first pump unit having a first pump case forming a first pump chamber, a first water inlet and a first water outlet being formed on the first pump case, the first pump chamber communicating with the first water inlet and the first water outlet;
a first check valve correspondingly connected with the first water outlet;
a second pump unit having a second pump case forming a second pump chamber, a second water inlet and a second water outlet being formed on the second pump case, the second pump chamber communicating with the second water inlet and the second water outlet;
a second check valve correspondingly connected with the second water outlet;
a first connector assembly having a first water incoming section, a second water incoming section and a first water outgoing section, the first water incoming section being correspondingly connected with the first check valve, the second water incoming section being correspondingly connected with the second check valve;
a second connector assembly having a third water incoming section, a second water outgoing section and a third water outgoing section, the second water outgoing section being correspondingly connected with the first water inlet, the third water outgoing section being correspondingly connected with the second water inlet;
a pipe body assembly including a first pipe body and a second pipe body, one end of the first pipe body correspondingly communicating with the first water outgoing section, one end of the second pipe body correspondingly communicating with the third water incoming section; and
a heat dissipation unit having an inlet and an outlet, the inlet correspondingly communicating with the other end of the first pipe body, the outlet correspondingly communicating with the other end of the second pipe body, the heat dissipation unit being formed with an internal communication chamber for a cooling liquid to flow through, the communication chamber communicating with the inlet and the outlet.

11. The water-cooling module as claimed in claim 10, wherein the first pump unit has a first communication pipe and a second communication pipe, two ends of the first communication pipe being respectively connected with the first check valve and the first water incoming section, two ends of the second communication pipe being respectively connected with the first water inlet and the second water outgoing section.

12. The water-cooling module as claimed in claim 10, wherein the second pump unit has a third communication pipe and a fourth communication pipe, two ends of the third communication pipe being respectively connected with the second check valve and the second water incoming section, two ends of the fourth communication pipe being respectively connected with the second water inlet and the third water outgoing section.

13. The water-cooling module as claimed in claim 10, wherein the first check valve has a first valve body formed with a first space and a second space inside, the first space having a first seat section, the second space having a second seat section, a first rod body having a first base section and a first sealing member, two ends of the first rod body extending to form a first extension end and a second extension end, the first and second extension ends being axially movably inserted in the first and second seat sections respectively, the first sealing member being disposed on one side of the first base section proximal to the first space, two ends of a first elastic member respectively abutting against the first base section of the first rod body and an inner wall face of the first valve body.

14. The water-cooling module as claimed in claim 13, wherein the first water outlet of the first pump unit correspondingly communicates with the first space and the first water incoming section correspondingly communicates with the second space.

15. The water-cooling module as claimed in claim 10, wherein the second check valve has a second valve body formed with a third space and a fourth space inside, the third space having a third seat section, the fourth space having a fourth seat section, a second rod body having a second base section and a second sealing member, two ends of the second rod body extending to form a third extension end and a fourth extension end, the third and fourth extension ends being axially movably inserted in the third and fourth seat sections respectively, the second sealing member being disposed on one side of the second base section proximal to the third space, two ends of a second elastic member respectively abutting against the second base section of the second rod body and an inner wall face of the second valve body.

16. The water-cooling module as claimed in claim 15, wherein the second water outlet of the second pump unit correspondingly communicates with the third space and the second water incoming section correspondingly communicates with the fourth space.

17. The water-cooling module as claimed in claim 10, further comprising a water reservoir, one side of the water reservoir correspondingly communicating with the pipe body assembly, the other side of the water reservoir correspondingly communicating with the inlet and the outlet of the heat dissipation unit.
